(19) United States
(12) Patent Application Publication
(10) Pub. No.: US 2022/0199955 A1
(43) Pub. Date: Jun. 23, 2022

(54) DISPLAY DEVICE AND MANUFACTRING METHOD THEREOF

(71) Applicant: Japan Display Inc., Tokyo (JP)

(72) Inventor: Hiraaki KOKAME, Tokyo (JP)

(21) Appl. No.: 17/691,179

(22) Filed: Mar. 10, 2022

Related U.S. Application Data
(63) Continuation of application No. PCT/JP2020/027912, filed on Jul. 17, 2020.

(30) Foreign Application Priority Data
Sep. 18, 2019 (JP) 2019-169788

(51) Int. Cl. H01L 51/52; H01L 51/56

(52) U.S. Cl. CPC H01L 51/5253; H01L 51/56; H01L 27/3276; H01L 2251/303; H01L 2227/323

(57) ABSTRACT

An oxidation protective film is continuously provided from the display area to the frame area so as to be in contact with the upper electrode. A first inorganic sealing film is provided on the substrate so as to cover the upper electrode and the oxidation protective film. An organic sealing film is provided on the first inorganic sealing film. A second inorganic sealing film is provided on the organic sealing film and is in direct contact with the first inorganic sealing film in a periphery of the organic sealing film. The oxidation protective film covers at least the contact area of the upper electrode in the frame area and is not provided in the periphery in which the first inorganic sealing film and the second inorganic sealing film are in direct contact with each other.

The present application is Bypass Continuation of International Application No. PCT/JP2020/027912, filed on Jul. 17, 2020, which claims priority from Japanese Application No. JP2019-169788 filed on Sep. 18, 2019. The contents of these applications are hereby incorporated by reference into this application.

### BACKGROUND OF THE INVENTION

### 1. Field of the Invention

The present invention relates to a display device and a method of manufacturing the display device.

### 2. Description of the Related Art

In a display device, a lower electrode and an upper electrode of a light emitting layer included in a display substrate need to be protected from moisture. In a case where a metal thin film is used for the lower electrode and the upper electrode of the light emitting layer, oxidation of the metal thin film may cause a problem, such as non-lighting. In particular, if the upper electrode is oxidized, a region in contact with the wiring becomes high in resistance. As such, a sealing layer is provided on the top surface of the display substrate. Additionally, for higher display quality, a protective film may be provided on the lower surface of the sealing film (the surface on the display substrate side) to absorb moisture.

JP2007-005047A discloses the display device directed to reducing deterioration of display quality due to moisture. The display device includes the organic EL layer between the anode wiring and the cathode wiring. Further, the thin film made of an alkaline earth metal or an oxide of alkaline earth metal is provided on the cathode wiring to serve as a moisture absorbent layer.

### SUMMARY OF THE INVENTION

In a case where the upper electrode of the display device (the cathode wiring in Patent Literature 1) is made of a metallic thin film, however, oxidation-reduction reaction occurs between the moisture absorbent layer provided immediately above the upper electrode and the upper electrode. As such, it is not possible to prevent the oxidation of the upper electrode continuously.

Further, even if a sealing layer is provided directly on the upper electrode, oxidation of the upper electrode is not sufficiently prevented. Specifically, in the films constituting the sealing layer, if oxygen atoms are contained in the material of the film on the upper electrode side, oxidation of the upper electrode may possibly occur. Further, even if oxygen atoms are not contained in the material of the film constituting the sealing layer, it is also conceivable that oxidation of the upper electrode may occur under an atmosphere in a process of manufacturing the film constituting the sealing layer.

One or more embodiments of the present invention have been conceived in view of the above, and an object thereof is to provide a display device capable of preventing oxidization of an upper electrode provided on an upper surface of an organic material layer.

In order to solve the above problems, a display device according to the present invention includes a substrate that includes a display area and a frame area, the display area including a pixel array unit, the frame area being other than the display area; an upper electrode that is electrically connected to wiring in a contact area provided in the frame area and is provided on an upper surface of the pixel array unit, the upper electrode being made of a metallic thin film; an oxidation protective film that is continuously provided from the display area to the frame area so as to be in contact with the upper electrode; a first inorganic sealing film that is provided on the substrate so as to cover the upper electrode and the oxidation protective film; an organic sealing film that is provided on the first inorganic sealing film; and a second inorganic sealing film that is provided on the organic sealing film and is in direct contact with the first inorganic sealing film in a periphery of the organic sealing film, wherein the oxidation protective film covers at least the contact area of the upper electrode in the frame area and is not provided in the periphery in which the first inorganic sealing film and the second inorganic sealing film are in direct contact with each other.

### BRIEF DESCRIPTION OF THE DRAWINGS

FIG. 1 is a schematic diagram illustrating a configuration of an organic EL display device according to an embodiment of the present invention;

FIG. 2 is a schematic plan view of an example of a display panel of the organic EL display device shown in FIG. 1;

FIG. 3 is a schematic diagram illustrating an example of III-III cross-section of FIG. 2;

FIG. 4 is a schematic plan view of the display panel of the organic EL display device shown in FIG. 1 in a case where a cathode contact portion is provided only on one side of a frame area;

FIG. 5 is a schematic enlarged view of a potion V of FIG. 4;

FIG. 6 is a schematic plan view of the display panel of the organic EL display device shown in FIG. 1 in a case where the cathode contact portion is provided on three sides of the frame area; and

FIG. 7 is a schematic enlarged view of a portion VII of FIG. 6.

### DETAILED DESCRIPTION OF THE INVENTION

Embodiments of the present invention will be described below in detail with reference to the accompanying drawings. The disclosure is merely an example, and appropriate modifications while keeping the gist of the invention that can be easily conceived by those skilled in the art are naturally included in the scope of the invention. The accompanying drawings may schematically illustrate widths, thicknesses, shapes, or other characteristics of each part for clarity of illustration, compared to actual configurations. However, such a schematic illustration is merely an example and not intended to limit the present invention. In this specification and each drawing, the same elements as those already described with reference to the already-presented drawings are denoted by the same reference numerals, and detailed description thereof may be appropriately omitted.

Further, in the detailed description of the present invention, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

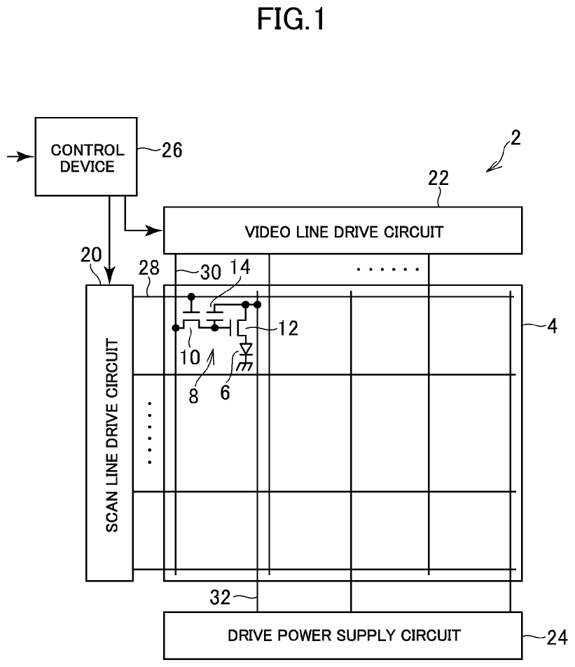

FIG. 1 is a schematic diagram showing a configuration of a display device according to an embodiment of the present invention by taking an example of an organic EL display device. An organic EL display device 2 includes a pixel array unit 4 that displays an image, and a drive unit that drives the pixel array unit 4. The organic EL display device 2 is configured such that a laminated structure of a thin film transistor (TFT) and an organic light-emitting diode (OLED) is formed on a base material. The schematic diagram shown in FIG. 1 is merely an example, and the present embodiment is not limited to this example.

The pixel array unit 4 includes pixels, each having an OLED 6 and a pixel circuit 8, arranged in a matrix. The pixel circuit 8 is composed of a plurality of TFTs 10 and 12 and a capacitor 14.

The drive unit includes a scan line drive circuit 20, a video line drive circuit 22, a drive power supply circuit 24, and a control device 26, and drives the pixel circuit 8 to control the emission of the OLED 6.

The scan line drive circuit 20 is connected to a scanning signal line 28 provided for each horizontal pixel array (pixel row). The scan line drive circuit 20 sequentially selects the scanning signal lines 28 in response to a timing signal from the control device 26 and applies a voltage to the selected scanning signal line 28 to turn on the switching TFT 10.

The video line drive circuit 22 is connected to a video signal line 30 provided for each vertical pixel array (pixel column). The video line drive circuit 22 receives a video signal from the control device 26, and, in accordance with the selection of the scanning signal line 28 by the scan line drive circuit 20, outputs a voltage corresponding to the video signal of the selected pixel row to each video signal line 30. The voltage is written to the capacitor 14 via the switching TFT 10 at the selected pixel row. The driving TFT12 supplies a current corresponding to the written voltage to the OLED 6. This causes the OLED 6 of the pixel corresponding to the selected scanning signal line 28 to emit light.

The drive power supply circuit 24 is connected to a drive power supply line 32 provided for each pixel column, and supplies a current to the OLED 6 via the drive power supply line 32 and the drive TFT 12 in the selected pixel row. In FIG. 1, the drive power supply line 32 is provided for each pixel column, but may be provided for each pixel row or provided for both.

The lower electrode 100 of the OLED 6 is connected to the drive TFT12. An upper electrode 104 of each OLED 6 is constituted by the electrode common to the OLEDs 6 of all the pixels. When the lower electrode 100 is formed as an anode, a high potential is applied, the upper electrode 104 becomes a cathode low potential is applied. When the lower electrode 100 is formed as a cathode, a low electric potential is entered in the lower electrode. In this case, the upper electrode 104 is an anode and supplied with a high electric potential.

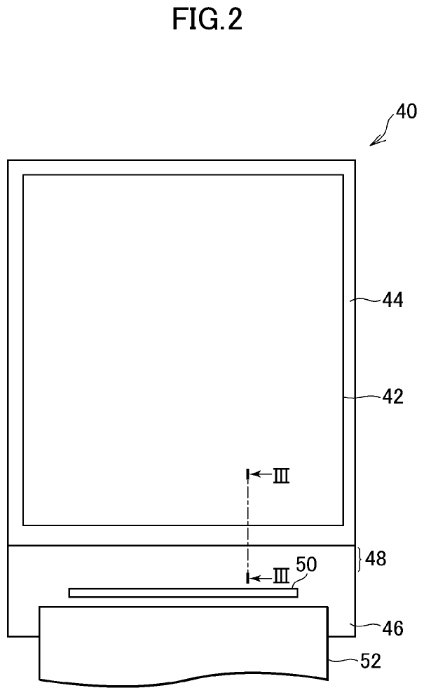

FIG. 2 is a schematic plan view of an example of a display panel of the organic EL display device 2 shown in FIG. 1. The pixel array unit 4 shown in FIG. 1 is provided in the display area 42 of the display panel 40. As described above, the OLEDs 6 are arranged in the pixel array unit 4. The upper electrode 104 described above forming the OLED 6 is formed commonly to the pixels to cover the entire display area 42. The frame area 44 is provided around the display area 42, and the scan line drive circuit 20, the video line drive circuit 22, the drive power supply circuit 24, and the control device 26 are disposed.

On one side of the frame area 44 of the display panel 40, which is rectangular, a component mounting area 46 and a bend area 48 are provided. The wiring leading to the display area 42 is disposed in the component mounting area 46 and the bend area 48. Further, the component mounting area 46 has a driver IC 50 constituting the drive unit and is connected to a flexible printed circuit board (FPC) 52. The FPC 52 is connected to the control device 26 and the circuits 20, 22, and 24, and has an IC mounted thereof.

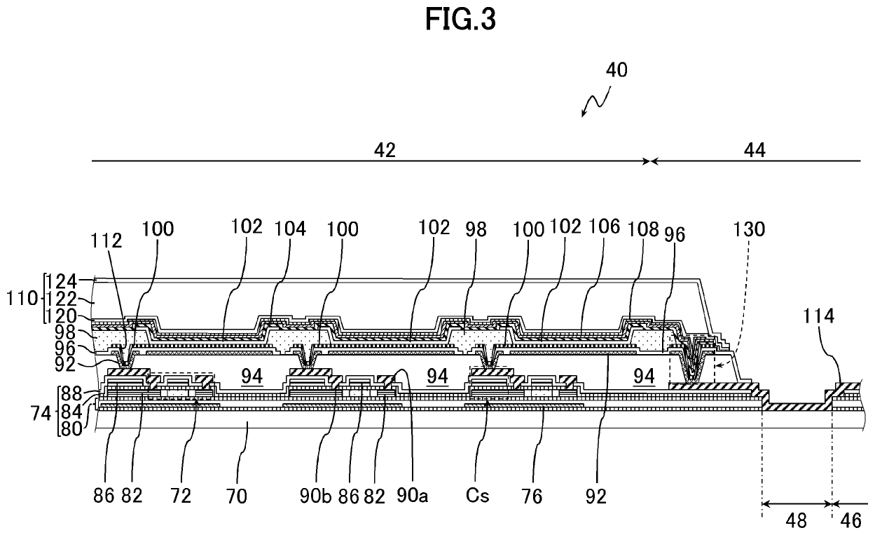

FIG. 3 is a schematic diagram illustrating an example of III-III cross-section of FIG. 2. The III-III cross-section mainly shows a cross-sectional structure of the display area 42 including NchTFT constituting the pixels, the frame area 44, and the bend area 48. In FIG. 3, hatching of some layers is omitted to make the cross-sectional structure easier to see.

The display panel 40 has a structure constituted by laminating a circuit layer 74 in which a TFT72 is formed, the OLEDs 6, and a sealing layer 110 for sealing the OLEDs 6 on a base material 70, for example.

The base material 70 is made of, for example, a transparent substrate such as glass and quartz, and a resin film containing a resin such as a polyimide-based resin. In a case where a resin film is used, for example, the base material 70 is formed by applying a resin material on a support substrate (not shown) and made flexible by removing the support substrate later. Here, polyimide is used for both the base material 70 and a counter substrate. However, any other resin material may be used if the base material has sufficient flexibility as a sheet display.

For example, a protective layer (not shown) is disposed on the sealing layer 110. In the present embodiment, the pixel array unit 4 has a top emission structure, and the light generated by the OLED 6 is emitted to the side opposite to the base material 70 (upward in FIG. 3). When a color filter method is employed as a coloring method for the organic EL display device 2, for example, a color filter is disposed between the sealing layer 110 and the protective layer (not shown) or on the counter substrate side. When white light generated by the OLED 6 passes through the color filter, for example, light rays of red (R), green (G), and blue (B) are produced.

The pixel circuit 8, the scanning signal line 28, the video signal line 30, and the drive power supply line 32 described above are formed on the circuit layer 74 of the display area 42. At least a portion of the drive unit may be formed as the circuit layer 74 on the base material 70 in an area adjacent to the display area 42. The terminals of the driver IC50 and the FPC 52 constituting the drive unit are electrically connected to the wiring 114 of the circuit layer 74 in the component mounting area 46.

As shown in FIG. 3, an undercoat layer 80 formed of an inorganic insulating material is disposed on the base material 70. The inorganic insulating materials include, for example, silicon nitride (SiNy), silicon oxide (SiOx), and composites thereof.

In the present embodiment, the undercoat layer 80 has a three-layer laminated structure of a silicon oxide film, a silicon nitride film, and a silicon oxide film. The lowermost silicon oxide film is provided to improve adhesion to the base material 70. The middle silicon nitride film is provided as a blocking film of moisture and impurities from the outside. The uppermost silicon oxide film is provided as a block film to prevent hydrogen atoms contained in the silicon nitride film from diffusing to the semiconductor layer side. The undercoat layer 80 is not limited to a three-layer laminated structure. The lamination may have more layers, or may be formed of a single layer or two layers.

When the undercoat layer 80 is formed, an LS film 76 may be formed at a position where a TFT 72 is formed later. The LS film 76 prevents a change in TFT properties caused by, for example, light from the back surface of the channel of the TFT 72. Further, the LS film 76 is formed of a conductive layer and given a certain potential, thereby providing a back-gate effect to the TFT 72. After the lowermost silicon oxide film is formed, the LS film 76 is formed in an island shape at the position where a driving transistor is formed. Subsequently, the middle silicon nitride film and the uppermost silicon oxide film are laminated. As described above, the LS film 76 is formed to be enclosed in the undercoat layer 80, but the structure is not limited thereto. The LS film 76 may be formed on the base material 70, and then the undercoat layer 80 may be formed.

In the display area 42, the TFT 72 is formed on the undercoat layer 80. Polysilicon TFT is taken as an example of the TFT 72, and only NchTFT is shown here. However, the present invention is not limited to this example, and PchTFT may be formed at the same time. The NchTFT has a semiconductor region 82 serving as a channel electrode and a source-drain electrode. The semiconductor region 82 is formed of polysilicon (p-Si), for example. Specifically, a semiconductor layer (p-Si film) is first provided on the base material 70. The semiconductor layer is then patterned to selectively leave a portion to be used in the circuit layer 74. The semiconductor region 82 is formed in this manner.

The gate electrode 86 is disposed on the channel portion of the TFT 72 through the gate insulating film 84. The gate insulating film 84 is typically formed of TEOS. Here, a silicon oxide film is used as the gate insulating film. The gate electrode 86 is formed by patterning a metal film formed by sputtering, for example. Here, the gate electrode 86 uses MoW (1st wiring). The gate electrode 86 also forms a storage capacitance line and is used to form a storage capacitance (Cs) between the polysilicon.

An interlayer insulating layer 88 is disposed on the gate electrode 86 so as to cover the gate electrode 86. The interlayer insulating layer 88 has a two-layer laminated structure of a silicon nitride film and a silicon oxide film. The two layers are laminated and then patterned, and whereby a portion of the interlayer insulating layer 88 at the position corresponding to the bend area 48 is removed. Further, the undercoat layer 80 exposed due to the removal of the interlayer insulating layer 88 is also removed by patterning. After the undercoat layer 80 is removed, the polyimide constituting the base material 70 is exposed. At this time, the polyimide surface may be partially eroded through etching of the undercoat layer 80 to cause film reduction.

At this time, a wiring pattern is formed under each of the step formed by the edge of the interlayer insulating layer 88 and the step formed by the edge of the undercoat layer 80. In such a wiring pattern, a routing wire, which is formed in the next step, is disposed over the wiring pattern when crossing the steps. Here, the gate electrode 86 is provided between the interlayer insulating layer 88 and the undercoat layer 80, and the LS film 76 is provided between the undercoat layer 80 and the base material 70. These layers are used to form the wiring pattern.

The conductive layer (2nd wiring) 92 is further formed to serve as a source-drain electrode and a routing wire. The conductive layer 92 is formed by patterning a metal film formed by sputtering, for example. A three-layer laminated structure of Ti, Al, and Ti is employed here. The storage capacitance (Cs) is formed by the interlayer insulating layer 88, the electrode formed of the conductive layer in the same layer as and the gate electrode of the TFT, and the electrode formed by the conductive layer in the same layer as the source-drain wiring of the TFT. The routing wire extends from the frame area 44 of the base material 70 to the component mounting area 46. A terminal for connecting the driver IC 50 and the FPC 52 is formed later.

The routing wire is formed so as to extend across the bend area 48 to the area to which the terminals of the FPC 52 are connected. As such, the routing wire extends across the steps of the interlayer insulating layer 88 and the undercoat layer 80. As described above, the wiring pattern by the LS film 76 is formed in the steps, and thus, even if the routing wire is disconnected at the recess of the step, the electrical connection can be maintained by contacting the LS film 76.

Subsequently, a flattening film 94 and a passivation film 96 are formed so as to cover the TFT 72 and the conductive layer 92. The flattening film 94 is formed of a resin material, for example. In particular, organic materials such as photosensitive acrylics are often used, because they have superior surface flatness compared to inorganic insulating materials formed by the chemical vapor deposition (CVD) method, for example. The passivation film 96 is formed of an inorganic insulating material such as SiNy. In the display area 42, the OLED 6 is formed on the passivation film 96.

The OLED 6 includes a lower electrode 100, an organic material layer 102, and an upper electrode 104. The OLED 6 is typically formed by laminating the lower electrode 100, the organic material layer 102, and the upper electrode 104 in this order from the base material 70.

If the TFT 72 shown in FIG. 3 is a driving TFT 12 having n-channels, the lower electrode 100 is connected to the source electrode 90a of the TFT 72. Specifically, after the flattening film 94 described above is formed, a contact hole 112 for connecting the lower electrode 100 to the TFT 72 is formed. For example, the surface of the flattening film 94 and the conductive portion formed in the contact hole 112 are patterned, whereby a lower electrode 100 connected to the TFT 72 is formed for each pixel. The lower electrode 100 may be formed of a transparent metal oxide, such as ITO and IZO. The lower electrode 100 may be provided by forming a thin film of metal, such as Ag and Al.

A bank 98 (also referred to as a rib) serving as a partition wall of a pixel area is formed on the structure described above. For example, after the lower electrode 100 is formed, the bank 98 is formed at the pixel boundary. Subsequently, the organic material layer 102 and the upper electrode 104 are laminated on the effective area of the pixel surrounded by the bank 98, i.e., the area where the lower electrode 100 is exposed.

Similarly to the flattening film 94, the bank 98 is formed of, for example, a resin material (e.g., photosensitive acrylic). Preferably, the edge of the bank 98 has a smooth tapered shape. If the open end has a steep shape, the organic material layer 102 may be poorly covered.

The flattening film 94 and the bank 98 have portions in contact with each other through an opening provided in the passivation film 96 between the flattening film 94 and the bank 98. These portions are opening for removing moisture or gas desorbed from the flattening film 94 through the bank 98 by heat treatment after the bank 98 is formed, for example.

The organic material layer 102 is typically formed by laminating a hole transport layer, a light emitting layer, and an electron transport layer in this order from the anode side. The organic material layer 102 may also have other layers. The other layers include, for example, a hole injection layer and an electron blocking layer disposed between the anode and the light emitting layer, and an electron injection layer and a hole blocking layer disposed between the cathode and the light emitting layer. As shown in FIG. 3, the organic material layer 102 may be continuously formed over the plurality of lower electrodes 100 and the banks 98 or may be selectively formed over each of the lower electrodes 100. As described above, the organic material layer 102 may have a plurality of layers, although some layers may be continuously formed on the plurality of lower electrodes 100 and the banks 98, and some of the other layers may be selectively formed on the respective lower electrodes 100.

After the organic material layer 102 is formed, an upper electrode 104 is formed. The upper electrode 104 covers the organic material layer 102 and the bank 98. The upper electrode 104 is formed as a uniform film (so-called solid film) extending over the entire display area 42. The organic material layer 102, and the lower electrode 100 and the upper electrode 104 sandwiching the organic material layer 102 constitute a light emitting element. The light emitting layer included in the organic material layer 102 emits light when an electric current flows between the lower electrode 100 and the upper electrode 104.

The upper electrode 104 is formed of a metallic thin film such as MgAg. When a metallic thin film is used for the organic EL display device 2 with a top-emission structure, the film thickness must be reduced to the extent that the light is transmitted. On the other hand, if the organic EL display device 2 employs a bottom-emission structure, the upper electrode 104 needs to be formed as a reflective electrode.

The top emission structure is employed here, and thus the upper electrode 104 is formed of MgAg as a thin film through which the light emitted from the organic EL layer is transmitted. According to the order of forming the organic material layer 102 as shown, the lower electrode 100 serves as an anode, and the upper electrode 104 serves as a cathode. The upper electrode 104 is formed over the display area 42 and a cathode contact portion 130 provided in the vicinity of the display area 42, and connected to the underlying conductive layer 92 at the cathode contact portion 130. The conductive layer 92 is connected to the further underlying wiring 114, and connected to the FPC 52 in the component mounting area 46.

After the upper electrode 104 is formed, an oxidation protective film 106 is formed. The oxidation protective film 106 is provided in the display area 42 and the frame area 44. In the frame area 44, the oxidation protective film 106 is provided so as to cover the cathode contact portion 130 in the vicinity of the display area 42. The oxidation protective film 106 is not provided at a peripheral portion of the sealing layer 110 to be described later in which the first inorganic sealing film 120 and the 2 inorganic sealing film 122 are in direct contact with each other.

The oxidation protective film 106 is formed of a compound (e.g., LiF) containing at least one of an alkali metal and an alkaline earth metal that have a larger ionization tendency than the metal used for the upper electrode 104. That is, the oxidation protective film 106 may be formed of only a compound containing an alkali metal having a larger ionization tendency than the metal used for the upper electrode 104 or only a compound containing an alkaline earth metal. Alternatively, the oxidation protective film 106 may be formed of a mixture of a compound containing an alkali metal having a larger ionization tendency than the metal used for the upper electrode 104 and a compound containing an alkaline earth metal. The oxidation protective film 106 may be formed of the same material as an optical adjustment layer (not shown) forming the pixel array unit 4 shown in FIG. 1.

One of the objects to provide the oxidation protective film 106 is to prevent oxidation of the upper electrode 104. That is, the upper electrode 104 is covered by the oxidation protective film 106 in the area relating to light emission of the organic material layer 102, thereby being protected from oxidation under an atmosphere containing oxygen or oxidation due to penetration of moisture.

After the oxidation protective film 106 is formed, a sealing layer 110 is formed. One of the functions of the sealing layer 110 is to cover the bank 98 and the organic material layer 102 to prevent moisture from the outside. As such, the sealing layer 110 has a high gas barrier property.

The sealing layer 110 has a laminated structure including a first inorganic sealing film 120, an organic sealing film 122, and a second inorganic sealing film 124 in this order. The first inorganic sealing film 120 is formed by, for example, depositing a silicon nitride film using the CVD method. The thickness of the first inorganic material film 120 is about 1 μm, for example. The organic sealing film 122 is formed of an acrylic or epoxy-based resin material, for example. The organic sealing film 122 is formed by, for example, applying a curable resin composition by any suitable method, such as an ink jet method or a screen printing method, and curing the obtained applied layer. The thickness of the organic sealing film 122 is about 10 μm, for example. Similarly to the first inorganic sealing film 120, the second inorganic sealing film 124 is formed by depositing a silicon nitride film using the CVD method. The thickness of the second inorganic sealing film 124 is about 1 μm, for example.

As shown in FIG. 3, an inorganic material film 108 may be provided between the oxidation protective film 106 and the first inorganic sealing film 120 for improving adhesion. The inorganic material film 108 is formed of an inorganic insulating material. Examples of inorganic insulating materials include compounds of silicon and oxygen such as silicon oxide (SiOx) and silicon oxynitride (SiON) and metal oxides such as alumina. The inorganic material film 108 may be composed of one of the above materials, or may be a mixture of two or more of materials. For reducing the influence on the display characteristics, the inorganic material film 108 is uniformly disposed at least in the display area 42. The inorganic material film 108 may be disposed on at least a part of the lower surface of the first inorganic sealing film 120. However, for improving adhesion, it is preferable that the inorganic material film 108 is provided at least at a peripheral portion of the frame area 44 in which the first inorganic sealing film 120 and the second inorganic sealing film 124 are in direct contact with each other. The thickness of the inorganic material film 108 is about 0.1 μm, for example. The thickness of the inorganic material film 108 may be set to, for example, 1/50 to ⅕ of the thickness of the first inorganic sealing film 120. The surface of the inorganic material film 108 (the surface where the first inorganic sealing film 120 is disposed) may be smooth (uniform in film thickness) or may have an uneven shape (uneven in film thickness). The uneven shape of the surface serves to increase the contact area with the first inorganic sealing film 120, thereby further improving adhesion. The inorganic material film 108 is formed by the CVD method, for example. The inorganic material film 108 having an uneven shape on its surface is formed by, for example, depositing a film by the CVD method through a mesh-shaped mask. When the surface unevenness affects the display characteristics of the display panel 40, the unevenness may be selectively formed in the area (frame area 44) surrounding the display area 42.

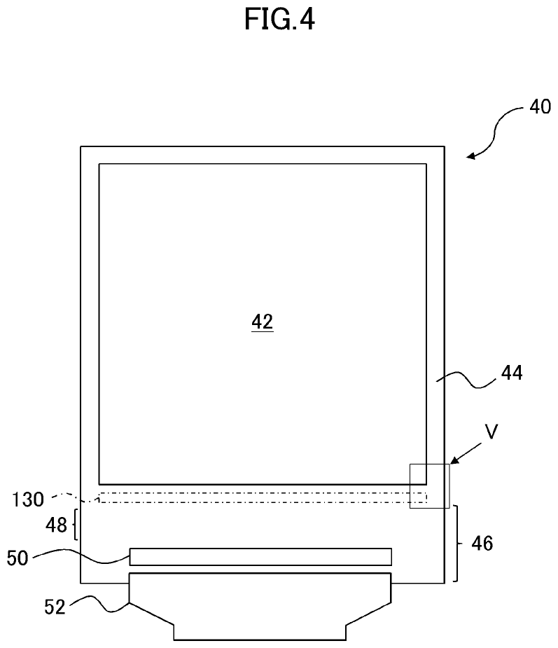

FIG. 4 is a schematic plan view of the display panel 40 of the organic EL display device 2 shown in FIG. 1 in a case where the cathode contact portion 130 is provided only on one side of the frame area 44. As shown in FIG. 4, the cathode contact portion 130 is provided in the area between the display area 42 and the FPC 52 in the organic EL display device 2.

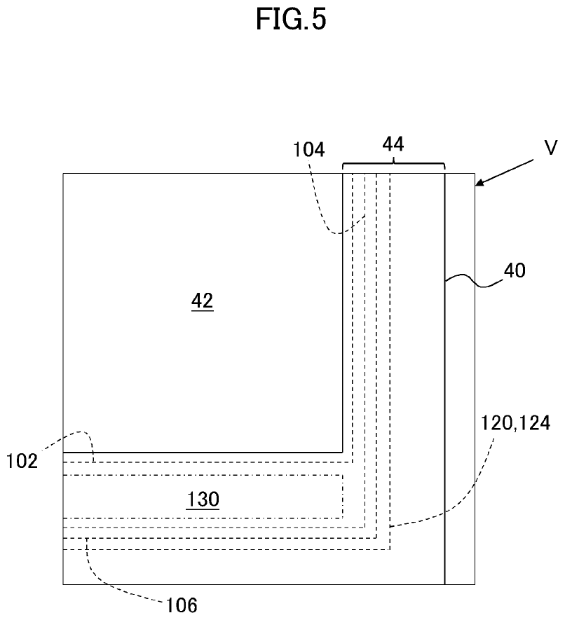

FIG. 5 is a schematic enlarged view of the section V in FIG. 4. In the organic EL display device 2 having the configuration as shown in FIG. 4, each layer is preferably positioned as shown in FIG. 5.

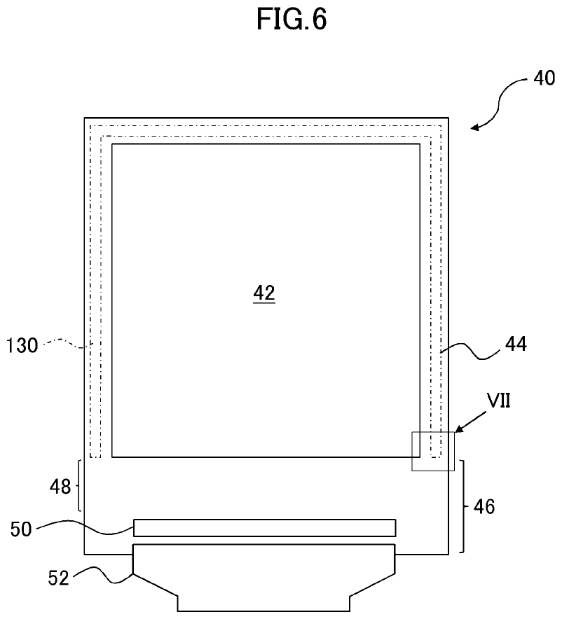

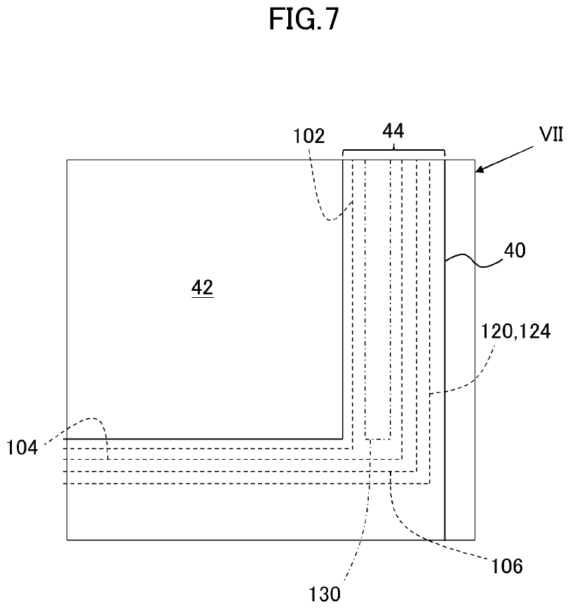

FIGS. 6 and 7 are examples of configurations of the organic EL display device 2 different from the configurations shown in FIGS. 4 and 5. FIG. 6 is a schematic plan view of the display panel 40 of the organic EL display device 2 shown in FIG. 1 in a case where the cathode contact portion 130 is provided on three sides of the frame area 44. FIG. 7 is a schematic enlarged view of the section VII in FIG. 6.

As described above, when the cathode contact portion 130 is provided so as to surround the periphery of the display area 42 as shown in FIG. 6, which is a different configuration of the organic EL display device 2 from that shown in FIGS. 4 and 5, the positional relationship of the layers is preferably as shown in FIG. 7.

In the following, referring to FIGS. 4 to 7, the positional relationship of the organic material layer 102, the upper electrode 104, the oxidation protective film 106, the sealing layer 110 (first inorganic sealing film 120, organic sealing film 122, second inorganic sealing film 124), and the cathode contact portion 130 will be described.

The organic material layer 102 is provided on the display area 42. The organic material layer 102 may be formed so as to individually cover each of the plurality of lower electrodes 100 as described above, or may be formed so as to continuously cover the entire display area 42.

The upper electrode 104 is preferably formed such that the edge of the upper electrode 104 is located closer to the edge of the display panel 40 than the edge of the organic material layer 102. In addition, the upper electrode 104 preferably extends continuously from the display area 42 to the cathode contact portion 130 and completely covers the cathode contact portion 130 in a plan view.

The oxidation protective film 106 is preferably formed so as to completely cover the formation region of the upper electrode 104 in a plan view. Further, the oxidation protective film 106 is preferably formed so as to completely cover at least the entire display area 42 and the entire cathode contact portion 130 in a plan view. In addition, it is preferable that the area between the display area 42 and the cathode contact portion 130 is formed so as to be continuously covered by the oxidation protective film 106.

It is preferable that the first inorganic sealing film 120 is formed so as to completely cover the oxidation protective film 106 in a plan view so that the edge of the oxidation protective film 106 is not exposed to the outside. In this regard, it is most simplified that the first inorganic sealing film 120 and the second inorganic sealing film 124 patterned simultaneously in the process. As a result, the second inorganic sealing film 124 also has the same shape as the first inorganic sealing film 120 in a plan view.

The organic sealing film 122 provided between the first inorganic sealing film 120 and the second inorganic sealing film 124 is formed so as to completely cover at least the display region 42 in a plan view. In addition, it is preferable that the first inorganic sealing film 120 and the second inorganic sealing film 124 are formed so as to be in contact with each other around the organic sealing film 122 so that the edge of the organic sealing film 122 is not exposed to the outside. Further, it is preferable that the first inorganic sealing film 120 and the second inorganic sealing film 124 are removed at a portion included in the bend area 48.

With the processing described above, the organic EL display device 2 is manufactured. A cover glass and a touch panel substrate may be provided on the sealing layer 110 as needed. In this case, for example, a filler made of a resin may be provided in order to fill the gap with the organic EL display device 2.

The present invention is not limited to the above embodiment, and various modifications can be made. For example, a replacement can be made with a configuration that is substantially the same as the configuration shown in the above-described embodiment, a configuration that exhibits the same operational effect, or a configuration that can achieve the same object.

Within the scope of the idea of the present invention, those skilled in the art can come up with various changes and modifications and it will be understood that these changes and modifications also fall into the scope of the present invention. For example, in each of the above-described embodiments, addition, deletion or redesign of a component, or addition, omission or condition change of a process, which are appropriately made by a person skilled in the art, are also included within the scope of the present invention as long as they remain the gist of the present invention.

What is claimed is:

1. A display device comprising:
a substrate that includes a display area and a frame area, the display area including a pixel array unit, the frame area being outside of the display area;
an upper electrode that is electrically connected to wiring in a contact area provided in the frame area and is provided on an upper surface of the pixel array unit, the upper electrode being made of a metallic thin film;
an oxidation protective film that is continuously provided from the display area to the frame area so as to be in contact with the upper electrode;
a first inorganic sealing film that is provided on the substrate so as to cover the upper electrode and the oxidation protective film;
an organic sealing film that is provided on the first inorganic sealing film; and
a second inorganic sealing film that is provided on the organic sealing film and is in direct contact with the first inorganic sealing film in a periphery of the organic sealing film, wherein
the oxidation protective film covers at least the contact area of the upper electrode in the frame area and is not provided in the periphery in which the first inorganic sealing film and the second inorganic sealing film are in direct contact with each other.

2. The display device according to claim 1, further comprising an inorganic material film that includes an oxygen atom, wherein
the inorganic material film is provided between the oxidation protective film and the first inorganic sealing film.

3. The display device according to claim 2, wherein
the inorganic material film includes at least one of a silicon oxide, a silicon oxynitride, or a metal oxide.

4. The display device according to claim 1, wherein
the oxidation protective film includes at least one of an alkali metal or an alkaline earth metal, each having a larger ionization tendency than a metal used for the upper electrode.

5. The display device according to claim 1, wherein
the oxidation protective film consists of a same material as an optical adjustment layer constituting the pixel array unit.

6. A method for manufacturing display device, the method comprising steps of:
providing a substrate that includes a display area and a frame area, the display area including a pixel array unit, the frame area being outside of the display area;
providing an upper electrode on an upper surface of the pixel array unit, the upper electrode being electrically connected to wiring in a contact area provided in the frame area and being made of a metallic thin film;
providing an oxidation protective film that is continuously provided from the display area to the frame area so as to be in contact with the upper electrode;
providing a first inorganic sealing film on the substrate so as to cover the upper electrode and the oxidation protective film;
proving an organic sealing film on the first inorganic sealing film; and
providing a second inorganic sealing film on the organic sealing film so as to be in direct contact with the first inorganic sealing film in a periphery of the organic sealing film, wherein
the oxidation protective film covers at least the contact area of the upper electrode in the frame area and is not provided in the periphery in which the first inorganic sealing film and the second inorganic sealing film are in direct contact with each other.
